(19) United States
(12) Patent Application Publication
(10) Pub. No.: US 2022/0213805 A1
(43) Pub. Date: Jul. 7, 2022

(54) STEAM TURBINE MEMBER

(71) Applicants: FUJI ELECTRIC CO., LTD., Kawasaki-shi (JP); National University Corporation Tokai National Higher Education and Research System, Nagoya-shi (JP)

(72) Inventors: Yuya NAKASHIMA, Hachioji-city (JP); Noritsugu UMEHARA, Nagoya-city (JP); Takaaki MIYACHI, Nagoya-city (JP); Motoyuki MURASHIMA, Nagoya-city (JP); Woo-Young LEE, Nagoya-city (JP); Takayuki TOKOROYAMA, Nagoya-shi (JP); Hiroyuki KOUSAKA, Gifu-city (JP); Miyu FURUHASHI, Gifu-city (JP)

(73) Assignees: FUJI ELECTRIC CO., LTD., Kawasaki-shi (JP); National University Corporation Tokai National Higher Education and Research System, Nagoya-shi (JP)

(21) Appl. No.: 17/701,162

(22) Filed: Mar. 22, 2022

Related U.S. Application Data
(63) Continuation of application No. PCT/JP2020/044606, filed on Dec. 1, 2020.

(30) Foreign Application Priority Data
Dec. 6, 2019 (JP) 2019-221495

(51) Int. Cl. F01D 25/00; C23C 16/26

(52) U.S. Cl. CPC F01D 25/00; F05D 2220/31; C23C 16/26

(57) ABSTRACT

A steam turbine member suppresses scale adhesion without impairing corrosion resistance performance and the like of a turbine. There is provided a steam turbine member having a deposited amorphous carbon film provided in an area on a base material at which scale deposition easily occurs, a steam turbine including the same, and a method for producing the steam turbine member.

### TECHNICAL FIELD

The present invention relates to steam turbine members. In particular, the present invention relates to steam turbine members in which adhesion of scale is reduced.

### BACKGROUND ART

To generate power, a steam turbine used in geothermal power generation converts thermal energy in high temperature and high pressure geothermal steam into rotational force via a turbine blade. In this case, the steam, having lost energy, is reduced in temperature and pressure. When the temperature and the pressure of the high temperature and high pressure geothermal steam are reduced, silica, calcium, iron sulfide, and the like, dissolved in the steam, precipitate and are deposited on a surface of the turbine blade. As the deposition progresses, a passage in which the geothermal steam flows may become clogged. This is called scale deposition. Scale deposition can be a cause of unexpected power station shutdown, reduces the utilization factor of the geothermal power station, and greatly reduces power generation of the geothermal power plant. Therefore, scale deposition is regarded as a problem to be solved.

It is known that scale deposition rate decreases in accordance with the pH of geothermal steam, and scale deposition can be suppressed to some extent by lowering the pH to 5 or less. As a specific method for realizing this, sulfuric acid, hydrochloric acid, or the like is injected into a geothermal fluid. Silica, one of the principal constituents of scale, can be reduced in rate of deposition by reducing the pH. Similarly, calcium precipitates in the form of calcium carbonate or the like, and such a calcium salt dissolves at a low pH, and hence, scale containing calcium can thus be reduced. Reducing the pH of the geothermal steam may, however, increase risk of corrosion damage to an iron-based material contained in the turbine.

Alternatively, there is known a technique in which effects on power reduction due to scale deposited on a surface of a blade may be suppressed by forming a nozzle vane and forming a throat width on an inlet side of the turbine to be larger than conventionally (Patent Document 1).

There is a known technique in which scale adhesion is suppressed by spraying a solution containing an organic material having a carboxyl group into geothermal steam (Patent Document 2). In this technique, the problem of corrosion resistance is avoided because no acid is injected.

### REFERENCE DOCUMENT LIST

### Patent Documents

Patent Document 1: JP 2003-214113 A
Patent Document 2: JP 2017-160842 A

### SUMMARY OF THE INVENTION

### Problem to be Solved by the Invention

The technique disclosed in Patent Document 1 cannot, however, fundamentally suppress scale adhesion itself. In addition, the technique disclosed in Patent Document 2 has a problem in that power generation efficiency is reduced because temperature of the steam is reduced and wetness thereof is increased due to solution spraying into the steam. It also has a problem of high cost since the solution containing the organic material must be continuously introduced. Furthermore, heat resistance temperature of the organic material is 200° C. or less, and hence, in power generation facilities in which geothermal steam having a high temperature of about 220° C. is used, the organic material may be thermally decomposed, and therefore, the expected effect of suppressing scale adhesion may not be obtained.

To solve the problems described above, there is a demand for a steam turbine member that can suppress scale deposition at high temperatures and high pressures without risk of damaging a member included in a turbine and limiting of operating conditions, and a steam turbine including the member.

### Means for Solving the Problem

In one aspect, the present invention relates to a steam turbine member having a deposited amorphous carbon film provided on a base material.

In the steam turbine member, the deposited carbon film is preferably a deposited carbon film having a relative intensity ratio (Id/Ig) between intensities at a D band (about 1360 cm⁻¹) and at a G band (about 1580 cm⁻¹) of a Raman spectrum of 0 to 1.5.

In the steam turbine member, the deposited carbon film preferably contains 0 to 40 at % of hydrogen and/or 0 to 30 at % of nitrogen.

In the steam turbine member, the deposited carbon film preferably has a thickness of 100 nm to 8 μm.

In the steam turbine member, a graphite amount G (%) in a carbon component and a hydrogen content H (at %) preferably satisfy, in a surface region of the deposited carbon film, a relationship represented by the following formula (1):

$$H \geq 1.5118 \times G - 40.603 \qquad ( 1 )$$

In the steam turbine member, the deposited carbon film preferably has a maximum height roughness Rz of not more than 6.3 μm.

In the steam turbine member, the deposited carbon film is preferably provided above the base material through an intermediate layer.

The steam turbine member is preferably a first stage stationary blade.

In another aspect, the present invention relates to a steam turbine including the steam turbine member according to any one of the aspects described above.

In another aspect, the present invention relates to a method for producing a steam turbine member having a deposited amorphous carbon film provided on a base material, including steps of: imparting a high energy heat source to a carbon source in a vacuum; and depositing, on the base material, a substance containing carbon generated in the previous step.

The method preferably further includes a step of supplying a hydrogen source and/or a nitrogen source to deposit hydrogen and/or nitrogen on the base material together with the carbon.

### Effects of the Invention

According to the present invention, a steam turbine member can be produced that will have an amount of adhering scale reduced to, for example, ¼ or less, and to even about 1/50th as compared with that produced by a conventional technique, a method is provided for producing the same, and a steam turbine is provided including the steam turbine member.

### BRIEF DESCRIPTION OF THE DRAWINGS

FIG. 1 is a graph illustrating a relationship between nitrogen concentration in each deposited carbon film of Examples 1(i) to 1(v) and adhesion amount of scale.

FIG. 2 is a graph illustrating a relationship between a hydrogen concentration in each deposited carbon film of Examples 2(i) to 2(iii) and an adhesion amount of scale.

FIG. 3 is a graph obtained by plotting graphite amount G (%) and hydrogen content H (at %) in a surface region of a deposited carbon film of Example 3, illustrating a relationship between G and H for achieving a small adhesion amount.

FIG. 4 is a conceptual diagram illustrating occurrence of scale deposition on a first stage stationary blade of a steam turbine in a conventional technique.

### MODE FOR CARRYING OUT THE INVENTION

Next, an embodiment of the present invention will be described with reference to the accompanying drawings. It is noted that the present invention is not limited to the embodiment described below.

### First Embodiment: Steam Turbine Member

According to a first embodiment, the present invention relates to a steam turbine member having deposited thereon a carbon film having an amorphous structure provided on a base material.

In the present invention, a steam turbine member refers to any of various members included in a steam turbine, and encompasses, but is not limited to, a steam turbine stationary blade, a steam turbine rotor blade, a steam turbine rotor, a bearing, a casing, a sealing part (seal fin) of a casing, a sealing part for preventing steam leakage, a main steam valve, a steam or hot water feed tube, a steam separator, a condenser, and a heat exchanger in an evaporator, and a steam condenser. In particular, it refers to, but is not limited to, a geothermal steam turbine member that comes into contact with geothermal steam and may have a scale deposition problem due to calcium or silica.

The base material constituting the steam turbine member may in general be a metal, and may be a base material of stainless steel or the like that is excellent in corrosion resistance, heat resistance, and wear resistance that is usually used in steam turbines. The base material may vary depending on the type of the member exemplified above and the position in the steam turbine, but it can include carbon steel, low alloy steel, martensitic stainless steel, austenitic stainless steel, and ferritic stainless steel. Examples of the base material of, for example, a steam turbine stationary blade and a seal fin include, but are not limited to, 13% Cr steel, and 17% Cr steel such as SUS 410, respectively. The base material is preferably mirror polished on the surface in an area for a deposited carbon film to be formed.

The deposited carbon film may be provided entirely on or partly on the base material of the steam turbine member. For example, it can be provided partially on an area of the base material at which scale easily adheres. The area of the base material to which scale easily adheres may vary among members, and is generally known in this field. When the steam turbine member is, for example, a steam turbine stationary blade, and a first stage stationary blade in particular, the area of the base material at which scale easily adheres is an area ranging from a back side apex to an edge of the profile, and the deposited carbon film is preferably provided at least on this area. Alternatively, when the steam turbine member is a seal fin, the area at which scale easily adheres is the surface of the seal fin.

As an example of the steam turbine member particularly demanded for suppression of scale adhesion, a first stage stationary blade will be further described with reference to a drawing. FIG. 4 is a conceptual diagram illustrating scale on a first stage stationary blade of a steam turbine when a conventional technique is used. Among stationary blades of about seven stages to about a dozen stages present in a steam turbine, first stage stationary blades 101a and 101b are fixed on a casing (not shown) in an area closest to an inlet of geothermal steam 100 to form a turbine cascade. Rotor blades 102 are also provided near the stationary blades. The geothermal steam 100 collides against the first stage stationary blades 101a and 101b in a direction illustrated with an arrow in FIG. 4, and then flows through between the stationary blades 101a and 101b adjacent to each other. In that case, silica or calcium dissolved in the geothermal steam adheres and precipitates in the form of scale S on a surface of the blade ranging from the apex to the edge of the profile in which the flow rate of the geothermal steam is minimum. On the other hand, as compared with that on the first stage stationary blades 101a and 101b, scale is unlikely to deposit on the rotor blades 102 disposed on a downstream side from the stationary blades 101a and 101b in the flowing direction of the geothermal steam. The scale S adhering to the first stage stationary blades 101a and 101b can be a cause of shutdown by clogging a passage for steam. In the present invention, a deposited carbon film is provided in an area corresponding to the scale S illustrated in FIG. 4, and thus, scale can be effectively prevented.

Next, the deposited amorphous carbon film will be described in detail. The deposited amorphous carbon film is a film containing amorphous carbon as a principal component, and it is produced by an evaporation method. In the present invention, the term “contain carbon as a principal component” refers to carbon being contained in an amount of 50% or more of total mass. The deposited amorphous carbon film may be representatively a diamond-like carbon (DLC) film which may be a chemically deposited film, or a physically deposited film. The deposited amorphous carbon film has a relative intensity ratio (Id/Ig) between intensities at a D band (about 1360 cm⁻¹) and at a G band (about 1580 cm⁻¹) of a Raman spectrum of preferably 0 to 1.5, and more preferably about 0.3 to 1.0. In particular, when the deposited carbon film is a chemically deposited film, the Id/Ig is, for example, preferably 0.0 to 1.0, and when the deposited carbon film is a physically deposited film, the Id/Ig is, for example, preferably 0.0 to 1.2. The Id/Ig is regarded as correlating with a ratio between Sp2 structure and Sp3 structure in the deposited carbon film having an amorphous structure. In the present invention, the Id/Ig having such a value is particularly effective for preventing scale deposition.

The deposited carbon film may be a deposited film consisting essentially of carbon alone. Also in this case, an element inevitably mixed in production may be contained. The deposited film containing carbon alone has advantages in that it can significantly suppress scale deposition as compared with a base material not provided with such a film, and it has high hardness and high wear resistance.

The deposited carbon film may be a deposited film containing hydrogen and/or nitrogen. Content of hydrogen in the deposited carbon film is preferably more than 0 and equal to or less than about 40 at % (atomic %), and it is more preferably about 10 at % or more and 40 at % or less. When the deposited carbon film contains hydrogen in such a content, scale adhesion can be effectively prevented. Content of nitrogen in the deposited carbon film is preferably over 0 and about 30 at % or less, and more preferably more than 0 and equal to or less than about 16 at %. When the deposited carbon film contains nitrogen in such content, scale adhesion can be effectively prevented. The deposited carbon film may contain both hydrogen and nitrogen. In this case, a total content of hydrogen and nitrogen may be about 40 to 60 at %, but it is not particularly limited.

Whether or not hydrogen and/or nitrogen is contained, the deposited carbon film of the present invention may contain a small amount of oxygen due to the production method employed. In addition, the deposited carbon film may contain a nonmetal element such as silicon (Si) derived from an intermediate layer, described below.

The thickness of the deposited amorphous carbon film may be uniform over the entire member, or it may be different among different areas. The thickness of the deposited carbon film is not particularly limited, and is preferably 100 nm to 8 μm, and it is more preferably 1 to 6 μm.

Since the surface of the deposited amorphous carbon film is relatively smooth, surface roughness of the deposited carbon film varies depending on the roughness of the base material on which the deposited carbon film is deposited. Therefore, desired surface roughness can be attained in accordance with selection of material of the base material and degree of surface polishing. In one aspect, the surface roughness of the deposited carbon film has a maximum height roughness Rz of preferably not more than 6.3 μm. The maximum height roughness Rz refers to a value measured with a stylus-type surface roughness tester.

In a surface region of the deposited amorphous carbon film, graphite amount G (%) in a carbon component and hydrogen content H (at %) preferably satisfies a relationship represented by the following formula (I):

$$H \geq 1.5118 \times G - 40.603 \qquad ( 1 )$$

wherein, 0≤H≤60, and 0<G. When the hydrogen content H in the deposited carbon film is greater than 60 at %, the product exhibits characteristics that are not diamond-like carbon, but are plastic, and hence, the content H is preferably 60 at % or less.

The surface region of the deposited carbon film refers to a region within about 2 nm from the outermost surface of the deposited carbon film. The graphite amount G (%) refers to percentage of number of graphite atoms to total number of atoms of the carbon component contained in the surface region of the deposited carbon film. More specifically, it refers to percentage of number of graphite atoms (mass) to total number of atoms (total mass) of diamond and graphite contained in the carbon component in the surface region of the deposited carbon film. The graphite amount G (%) in the surface region can be obtained by X-ray absorption fine structure (XAFS) analysis. On the other hand, the hydrogen content H (at %) refers to percentage of number of hydrogen atoms to total number of atoms contained in the surface region of the deposited carbon film. The hydrogen content H (at %) in the surface region can be obtained by XAFS analysis and/or elastic recoil detection analysis (ERDA).

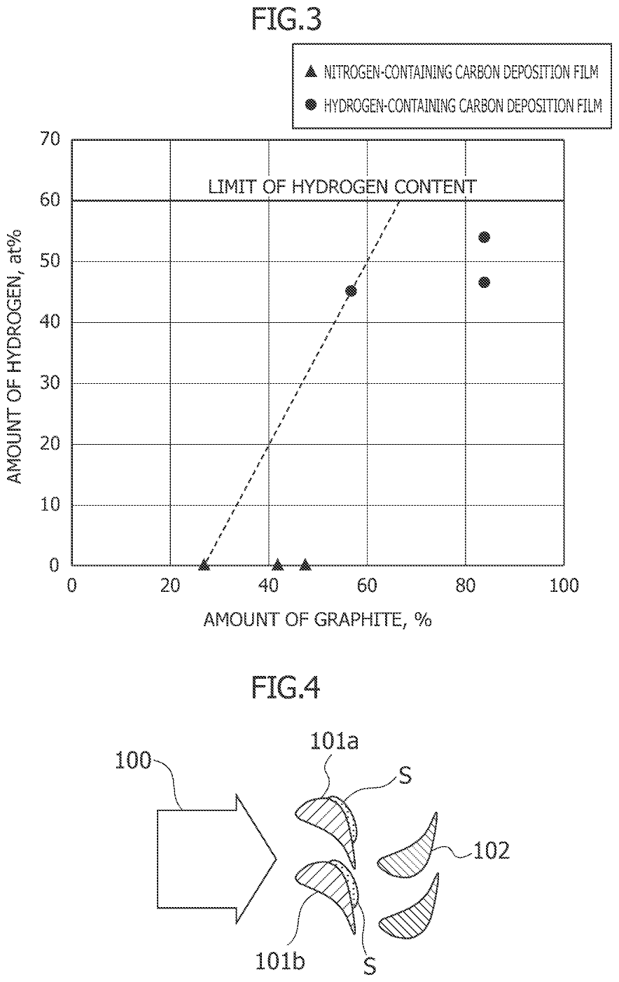

The formula mentioned above will now be described in more detail with reference to FIG. 3. FIG. 3 illustrates a composition in a surface region of a deposited carbon film of an example, described below, plotted with G on the horizontal axis and H on the vertical axis; a broken straight line shown in this graph indicates H=1.5118×G−40.603 (0≤H≤60). At the surface region of the deposited carbon film, when G and H satisfy 0<G and 0≤H≤60, and satisfy a relationship that they are present on the broken line or in a region to the left side of the broken line, the adhesion amount of scale can be suppressed to be very small. More specifically, such a deposited carbon film can reduce the adhesion amount of scale to about 1/20 or less as compared with that in a steam turbine member not provided with the deposited carbon film. In one aspect, from the viewpoint of production control and the like, the surface region preferably has a composition in which the content H in the surface region is 10 to 60 at %, and preferably 20 to 50 at %, and the amount G (%) satisfies the formula (1) with the content H falling in this range.

The deposited carbon film may further contain nitrogen in the surface region, and it may contain a trace component such as oxygen or silicon so long as the content H and the amount G satisfy the relationship of the formula (1). The graphite amount in the surface region is adjusted, and in particular, is reduced by containing nitrogen in the deposited carbon film, and thus, a steam turbine member capable of greatly reducing adhesion amount of scale can be obtained.

The deposited amorphous carbon film may be deposited in contact with the surface of the base material, or it may be deposited on an intermediate layer provided on the surface of the base material. The intermediate layer may be a material that improves adhesion between the base material and the deposited carbon film, and it may be a layer containing ceramic or metal. Examples include, but are not limited to, a metal compound containing a metal nitride such as chromium mononitride (CrN) or a metal oxide such as titanium dioxide (TiO₂), a silicon compound such as silicon nitride (SiC), and elemental silicon. The intermediate layer may be a single layer containing one compound, or it may be two or more layers each containing different compounds. Thickness of the intermediate layer is not particularly limited, and it can be appropriately determined by those skilled in the art.

A steam turbine member having such a deposited carbon film constitutes a steam turbine together with other members, and it is used in power generation facilities, particularly in geothermal power generation facilities. The steam turbine may include, for example, a bearing fixed on a base, a steam turbine rotor rotatably supported by the bearing, and a casing housing the steam turbine rotor. On a peripheral surface of the casing, a steam inlet to which steam is supplied from a geothermal steam well, and a steam outlet are provided. In the steam turbine rotor, a plurality of rotor blades are fixedly disposed at prescribed intervals along the shaft direction between the steam inlet and the steam outlet within the casing, stationary blades corresponding to these rotor blades are fixed on the casing, and the stationary blades and the rotor blades are alternately disposed along the shaft direction. The casing and the rotor may have seal fins arranged in the shaft direction to oppose the tips of the rotor blades and the stationary blades, respectively. A condenser connected to the steam outlet of the casing includes a nozzle for spraying cooling water so as to cool and condense steam that has been used in the turbine. In a geothermal binary power generation system, a heat exchanger is provided in a steam condenser to cool and condense an operation medium that has been used in the turbine. In one, two, or more of such members included in a steam turbine, the member including the deposited carbon film according to the present invention can be used, and thus, shutdown and deterioration of power generation efficiency, which are caused by scale deposition, can be prevented.

Next, a steam turbine member of the present invention will be described from the viewpoint of a production method. A method for producing a steam turbine member having a deposited amorphous carbon film provided on a base material according to the present invention includes the following steps:

(1) a step of imparting a high energy heat source to a carbon source in a vacuum, and

(2) a step of forming the deposited amorphous carbon film by depositing, on the base material, a substance containing carbon generated in the previous step.

The method for producing a steam turbine member can be performed by depositing the deposited carbon film on the base material by a dry plating method, and it can include the steps 1 and 2 described above. Examples of such a method include chemical vapor deposition (CVD) using a hydrocarbon gas as a carbon source, and physical vapor deposition (PVD) using solid carbon as a carbon source, and the steam turbine member of the present invention can be produced by either method. An example of chemical vapor deposition includes plasma CVD, and examples of physical vapor deposition include evaporation, ion plating, and sputtering, although this is not so limited.

In performing the production method, a base material having been processed into a shape of a desired member is prepared. The types of metals for the base material have been described above. The method may include, before performing the steps 1 and 2, a step of mirror polishing a surface of an area of the base material in which the deposited carbon film is to be provided. Alternatively, the method can include a step of providing an intermediate layer on a surface of an area of the base material on which the deposited carbon film is to be provided. The intermediate layer can be formed by chemical vapor deposition or physical vapor deposition in the same way as the deposited carbon film. The method may include, in addition to the steps 1 and 2, a step of supplying a hydrogen source and/or a nitrogen source to deposit hydrogen and/or nitrogen together with carbon on the base material.

In one aspect of the production method, a production method employing chemical vapor deposition, and in particular, DC pulse plasma CVD will now be described. Plasma CVD can be performed with an apparatus including, mainly in a vacuum chamber, means for introducing a hydrocarbon gas as a carbon source, means for applying a DC pulse bias to a member to be subjected to film deposition, and means for supporting a base material. As a hydrocarbon gas, methane, ethane, acetylene or the like can be used, and such a hydrocarbon gas can be selected in accordance with purposes by those skilled in the art.

In the DC pulse plasma CVD, a DC pulse bias having a negative potential with respect to a grounded film forming vessel is applied to the turbine material in the first step, and thus, plasma is generated around the base material, and a hydrocarbon gas such as methane is introduced into the plasma generation region. In this manner, methane is decomposed by plasma, and a deposited carbon film containing hydrogen is deposited on the base material, and thus, the second step can be performed. In this film deposition, a negative voltage to be applied to the base material is controlled to change collision energy of decomposed methane, and thus, a degree of decomposition of methane can be controlled to control hydrogen content in the resultant deposited carbon film. Specific conditions for attaining a desired hydrogen content in the deposited carbon film can be appropriately determined by those skilled in the art based on preliminary experiments and the like. In plasma CVD, a deposited carbon film containing hydrogen can be produced by simultaneously supplying a carbon source and a hydrogen source. It is noted that chemical vapor deposition is not limited to plasma CVD, and a chemically deposited carbon film can also be produced by employing another type of chemical vapor deposition.

Chemical vapor deposition such as plasma CVD is advantageous for producing a deposited carbon film containing hydrogen in particular. Since a hydrocarbon gas is used as a carbon source, a substance containing carbon to be deposited in the second step easily reaches various areas on the surface of the base material, and hence, this method has an advantage in that a film is easily deposited on a freely selected area on the base material.

Next, as a second aspect of the production method, physical vapor deposition is employed. Physical vapor deposition can be performed with an apparatus including, mainly in a vacuum chamber, a target such as solid carbon, means for generating a high energy heat source, and means for supporting a base material. In arc ion plating, an example of physical vapor deposition, vacuum arc discharge is generated between a cathode (negative electrode) of a target corresponding to a carbon source and an anode (positive electrode) to evaporate carbon particles from a surface of the target in the first step. The carbon particles pass through plasma to be positively charged, and in the second step, the positively charged carbon particles are deposited on the base material to which a negative bias voltage is applied, and thus, a deposited carbon film can be deposited. Furthermore, simultaneously with depositing the particles on the base material, a nitrogen ion beam may be introduced, and thus, a physically deposited carbon film containing nitrogen can be deposited. Nitrogen content in the deposited carbon film can be controlled by changing an amount of nitrogen gas introduced at this point. When hydrogen gas is used instead of nitrogen gas, a physically deposited carbon film containing hydrogen can be similarly deposited. It is noted that physical vapor deposition is not limited to arc ion plating, and a physically deposited carbon film can be similarly produced by employing another type of physical vapor deposition. In physical vapor deposition, means for movably supporting the base material is preferably provided depending on the shape or specification of the base material for purposes of depositing carbon particles which have greater difficulty in reaching a desired area than a hydrocarbon gas.

Physical vapor deposition is advantageous for producing a deposited carbon film containing nitrogen in particular, and it is also employed for producing a deposited carbon film containing both nitrogen and hydrogen. In this case, with a hydrogen gas used as a hydrogen source, a film can be produced by introducing both nitrogen gas and hydrogen gas into a vacuum chamber. Another advantage of physical vapor deposition is that a deposited carbon film having a desired composition can be produced.

A composition of the surface region is a layered product of methane, which can be used as a raw material gas in plasma CVD, having been decomposed by plasma to be converted into radicals. Accordingly, there is no correlation between a hydrogen content in the entire deposited carbon film and the composition of the surface region. In order to obtain a composition satisfying the formula (1), it is preferable to deposit a film by plasma CVD with methane used as a raw material gas. When a condition for applying plasma is changed, a hydrogen content H (at %) and a graphite amount G (%) in the carbon component in the surface region satisfying the formula (1) can be adjusted.

The steam turbine member including the base material having, in a desired area, the deposited carbon film produced as described above can be further combined with another turbine member to produce a steam turbine.

The method for producing a steam turbine member according to the present embodiment encompasses, in addition to production of a new steam turbine member, a method for repairing a steam turbine member. In this case, a part of a surface of a base material is subjected to a polishing treatment or the like if necessary, and then, a deposited carbon film is deposited in a necessary area in the same manner as in the production method of the present embodiment to repair and produce a steam turbine member.

### EXAMPLES

The present invention will now be described in more detail with reference to examples. It is noted, however, that the present invention is not limited to these examples.

### Example 1

An amorphous physically deposited carbon film was deposited on a base material by physical vapor deposition, and characteristics of the film were evaluated. As the base material, a turbine base material of martensitic stainless steel (SUS 420J1) having a diameter of 22.5 mm and h of 4 mm was used. In this example, no intermediate layer was provided, and a surface of the base material was mirror polished to deposit a deposited carbon film (DLC) directly on the base material.

In a film deposition apparatus, filtered arc deposition was employed. In this method, graphite used as a target is set on the cathode, a discharge phenomenon is caused on the cathode to evaporate and ionize graphite, the ions thus generated are transported by a magnetic field to a material to be subjected to film deposition, and thus, a DLC is deposited. As a specific structure of the apparatus, T-FAD (see, for example, J. Vac. Soc. Jpn. Vol. 51, No. 1, pages 20-25, 2008) was used. As conditions for film deposition, a back pressure was set to 4×10⁻³ Pa, an arc current was set to 50 A, and a bias was set to −30 V. Before the film deposition, the turbine base material as a material to be subjected to film deposition was cleaned by argon sputtering for 10 min. Into this film deposition chamber, N₂ gas was introduced in the form of an ion beam. The amount of the nitrogen gas to be introduced was set to 0, 5, 10, 15, or 20 sccm to deposit DLCs respectively having different nitrogen contents.

In this manner, samples of a steam turbine member were produced, in each of which a deposited carbon film having a nitrogen content of 0% (Example 1(i)), 5 at % (Example 1(ii)), 12 at % (Example 1(iii)), 16 at % (Example 1(iv)), or 20 at % (Example 1(v)) was provided in a thickness of 200 to 300 μm on the base material. Also, a sample of the base material with no deposited carbon film (Comparative Example) was prepared.

The samples of Examples 1(i) and 1(v) were measured for a Raman scattering spectrum with a laser beam of 532 nm using a Raman spectroscopic instrument, and spectral fitting was performed to obtain Id/Ig of the deposited carbon films. As a result, the Id/Ig was about 0.3 in Example 1(i), about 0.4 in Example 1(ii), about 0.6 in Example 1(iii), about 0.9 in Example 1(iv), and about 1.0 in Example 1(v). The maximum height roughness Rz of each of the surfaces of these deposited carbon films was less than 6.3 μm.

In order to confirm the effect of suppressing scale adhesion, silica, which causes the most scale problems, was selected as an evaluation target, and an adhesion test was performed on the samples of Examples 1(i) to 1(v) and the Comparative Example. To simulate geothermal steam, silicic acid for causing silica precipitation was dissolved to yield a supersaturated solution containing NaCl that is contained in geothermal steam. The resulting solution was adjusted in pH with hydrochloric acid to a pH at which silica was easily precipitated. A specific composition of a test solution was 200 mmol/l NaCl and 40 mmol/l NaSiO₃ adjusted to pH 8.5 with HCl. Each of the samples of Examples 1(i) to 1(v) and the comparative example was immersed in this solution, and it was held at 50° C. for 3 days. Silica was precipitated in a form of a gel by the immersion process. Subsequently, the silica gel was removed from the test solution, and the sample was held in the remaining solution at 50° C. for 1 week, and it was then dried. The temperature-holding and the drying process caused silica to adhere to the turbine material sample surface. Next, in order to evaluate silica which rigidly adhered to the sample, the surface of the turbine material sample was washed with running water, and amounts of residual silica were evaluated by energy dispersive X-ray spectroscopy (EDX). Adhesion amount of silica was calculated based on a detection intensity of silicon (Si), a constituent element of silica, and a Si increment A wt % was calculated based on differences between amounts of Si detected before and after the silica adhesion test.

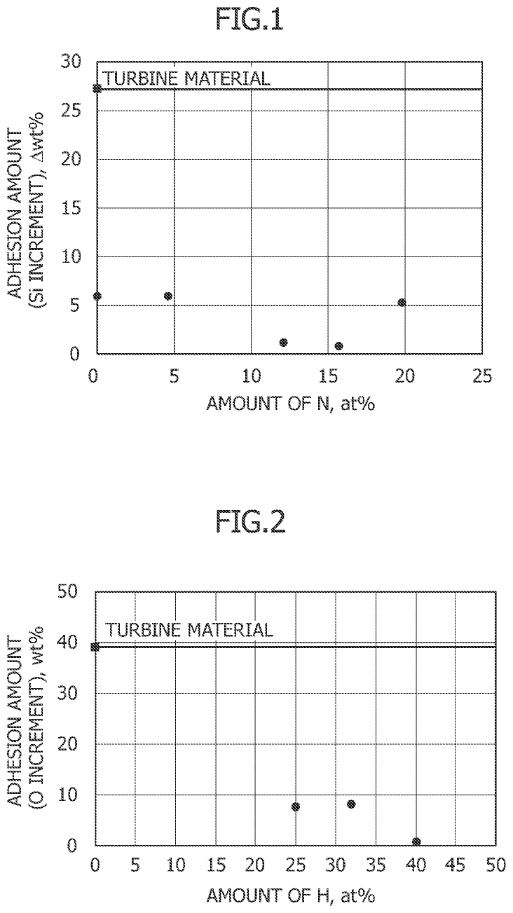

FIG. 1 is a graph illustrating a relationship between a nitrogen concentration in the deposited carbon film of each of Examples 1(i) to 1(v), and the adhesion amount of scale (Si increment obtained by EDX measurement). In this graph, a Si increment in the sample of the comparative example in which the deposited carbon film was not deposited is also illustrated as “Turbine Material”. Based on the results illustrated in FIG. 1, the adhesion amount of silica was largely suppressed in all of the samples of Examples 1(i) to 1(v) as compared with that in the sample of the Comparative Example. The adhesion amount of silica could be further reduced by including nitrogen in the deposited carbon film.

Each of these samples was photographed after the temperature holding, the drying treatment, and washing with running water to compare the appearance (photographs not shown). As a result, silica adhered to and covered the entirety of the sample having no film, but only adhered locally to the sample having the DLC deposited. It was also confirmed that the adhesion amount of silica was reduced in the DLC having a large nitrogen content as compared with that in the DLC having a small nitrogen content. In particular, the adhesion amount of silica was most greatly reduced in the DLC having a nitrogen content of 15 at %. Furthermore, even when adhesion of silica was found on the DLC, the silica was found to be cracked, peeled or the like on the DLC by SEM observation, and it was confirmed to have very weak adhesion. On the other hand, in the sample having no film deposited, very thick silica was deposited, and the silica was not found to be cracked, peeled or the like.

### Example 2

A chemical deposited amorphous carbon film was deposited on a base material by plasm CVD, and characteristics of the film were evaluated. As the base material, a base material similar to that of Example 1 was used, a surface of the base material was mirror polished in the same manner as in Example 1, and a deposited carbon film was deposited without providing an intermediate layer.

In a film deposition apparatus, DC pulse plasma CVD was employed (see, for example, Fabrication of Thin Solid Coating and Tribology with Plasma and Ion Beam Process, Journal of the Japan Society of Precision Engineering, 2017, vol. 83, No. 4, pages 319-324). When Ar plasma is generated using a DC pulse around a material to be subjected to film deposition, and methane gas is introduced thereto as a carbon source, the methane gas being decomposed by plasma to form a deposit as a DLC on the material to be subjected to film deposition. As conditions for film deposition, a chamber pressure was set to 40 Pa, and before film deposition, a turbine base material as the material to be subjected to film deposition was cleaned by argon sputtering. In order to provide an intermediate layer between the DLC and the material to be subjected to film deposition, 6 sccm of Ar, 30 sccm of CH₄, and 2 sccm of TMS (tetramethylsilane) were introduced, a bias of −600 V was applied, and a film deposition time was set to 2 min to provide a silicon-rich intermediate layer. Thereafter, 12 sccm of Ar and 60 sccm of CH₄ were introduced, and a bias to the material on which a film is to be deposited was changed to −400, −500, or −700V, to deposit DLCs respectively having different hydrogen contents.

In this manner, samples of a steam turbine member were produced, in each of which a deposited carbon film having a hydrogen content of 25 at % (Example 2(i)), 32 at % (Example 2(ii)), or 40 at % (Example 2(iii)) was provided on the base material. A sample of the base material not provided with a deposited carbon film (Comparative Example) was the same as that described in Example 1.

The samples of Example 2 were measured for Id/Ig of the deposited carbon films using a Raman spectroscopic instrument. As a result, the Id/Ig was about 0.54 in Example 2(i), about 0.42 in Example 2(ii), and about 0.28 in Example 2(iii). The maximum height roughness Rz of each of the surfaces of these deposited carbon films was less than 6.3 μm.

Verification of the effect of suppressing scale adhesion was performed in the same manner as in Example 1. In Example 2, an adhesion amount of silica was calculated based on a detection intensity of oxygen (O), a constituent element of silica, and an O increment A wt % was calculated based on a difference between amounts of 0 detected before and after the silica adhesion test.

FIG. 2 is a graph illustrating a relationship between a hydrogen concentration in the deposited carbon film of each of Examples 2(i) to 2(iii), and the adhesion amount of scale (O increment obtained by EDX measurement). In this graph, an O increment in the sample of the comparative example in which the deposited carbon film was not deposited is also illustrated as “Turbine Material”. Based on the results illustrated in FIG. 2, the adhesion amount of silica was greatly suppressed in all of the samples of Examples 2(i) to 2(iii) as compared with that in the sample of the Comparative Example. The adhesion amount of silica was further reduced by including hydrogen in the deposited carbon film.

### Example 3

Samples of a steam turbine member were produced, each including a base material on which a nitrogen-containing carbon deposition film was provided in the same manner as in Example 1 or a hydrogen-containing carbon deposition film was provided in the same manner as in Example 2. The nitrogen-containing carbon deposition film was produced to have a nitrogen content, in the entire deposited carbon film, of 30.8 at % (Example 3(i)), 32.0 at % (Example 3(ii)), or 34.8 at % (Example 3(iii)). The hydrogen-containing carbon deposition film was produced to have a hydrogen content, in the entire deposited carbon film, of 81.3 at % (Example 3(iv)), 77.7 at % (Example 3(v)), or 77.7 at % (Example 3(vi)).

In the same manner as in Examples 1 and 2, each of the samples of Example 3 was examined for effects of suppressing scale adhesion. Furthermore, before performing a scale adhesion experiment, composition of a surface region (a region within 2 nm from the surface) of the deposited carbon film of each of Examples 3(i) to 3(vi) was measured. A graphite amount G (%) in the surface region was analyzed by XAFS analysis. A hydrogen content H (at %) was measured by ERDA. Nitrogen content was analyzed by X-ray photoelectron spectroscopy. FIG. 3 is a graph obtained by plotting the relationship between H and G in the surface region of the deposited carbon film of each of Examples 3(i) to 3(vi). The composition of the surface region and the adhesion amount of silica in each sample of Example 3 are shown in following Table 1. The adhesion amount of silica is shown as a value obtained by assuming that the adhesion amount in a conventional turbine material having no deposited carbon film is 1.

TABLE 1

| Example | G (%) | H (at %) | N (at %) | Adhesion Amount |
|---|---|---|---|---|
| 3 (i) | 27 | | 17.3 | 0.04 |
| 3 (ii) | 42 | | 19.8 | 0.28 |
| 3 (iii) | 47 | | 0 | 0.31 |
| 3 (iv) | 57 | 45 | | 0.02 |
| 3 (v) | 84 | 46 | | 0.20 |
| 3 (vi) | 84 | 54 | | 0.06 |

In a conventional geothermal power generation plant in which serious scale deposition occurs, the steam turbine sometimes stopped due to scale deposition about 1 year after starting operation. Moreover, continuous operation for 4 years or more without shutdown is essential. In addition, design service life of a steam turbine is 20 years, and hence, it is most preferable that scale deposition be suppressed for 20 years. Therefore, as an effect of suppressing scale adhesion, scale adhesion is suppressed preferably to ¼ or less, and most preferably to 1/20 or less of the current situation. In this point, in Example 1, the adhesion amount of silica could be suppressed to ¼ or less in the turbine material on which the deposited carbon film having a nitrogen content of 0 to 20 at % was deposited as compared with that in the conventional turbine material in which no deposited carbon film was deposited, as illustrated in FIG. 1. Furthermore, in the turbine material on which the deposited carbon film having a nitrogen content of 16 at % was deposited, which exhibited the highest effect, it was confirmed that the adhesion amount of silica could be reduced to 1/20 or less. Furthermore, in the turbine material on which the deposited carbon film having a hydrogen content of 40 at % was deposited in Example 2, the adhesion amount of silica could be reduced to ¼ or less. In addition, as shown in Example 3, when the surface region had a composition satisfying the relational formula of the graphite content G (%) and the hydrogen content H (at %), the adhesion amount of silica could be reduced the most to 1/40 or less.

It was confirmed, through these examples, that a steam turbine member can be produced in which scale adhesion is suppressed without the need to spray a solution, which contributes to deterioration of power generation efficiency and increases costs.

### REFERENCE SYMBOL LIST

101a, b First stage stationary blade
102 Rotor blade
100 Geothermal steam
S Scale

1. A steam turbine member, comprising a deposited amorphous carbon film provided on a base material.

2. The steam turbine member according to claim 1, wherein the deposited carbon film is a deposited carbon film having a relative intensity ratio (Id/Ig) between intensities at a D band and at a G band of a Raman spectrum of 0 to 1.5.

3. The steam turbine member according to claim 1, wherein the deposited carbon film contains 0 to 40 at % hydrogen and/or 0 to 30 at % nitrogen.

4. The steam turbine member according to claim 1, wherein the deposited carbon film has a thickness of 100 nm to 8 μm.

5. The steam turbine member according to claim 1, wherein a graphite amount G (%) in a carbon component and a hydrogen content H (at %) satisfy, in a surface region of the deposited carbon film, a relationship represented by the following formula (1):
$$H \geq 1.5118 \times G - 40.603 \qquad ( 1 )$$

6. The steam turbine member according to claim 1, wherein the deposited carbon film has a maximum height roughness Rz of at most 6.3 μm.

7. The steam turbine member according to claim 1, wherein the deposited carbon film is provided above the base material through an intermediate layer.

8. The steam turbine member according to claim 1, wherein the steam turbine member is a first stage stationary blade.

9. A steam turbine, comprising the steam turbine member according to claim 1.

10. A method for producing a steam turbine member having a deposited amorphous carbon film provided on a base material, comprising steps of:
imparting a high energy heat source to a carbon source in a vacuum; and
depositing, on the base material, a substance containing carbon generated in the previous step.

11. The method according to claim 10, further comprising a step of supplying a hydrogen source and/or a nitrogen source to deposit hydrogen and/or nitrogen on the base material together with the carbon.

12. The steam turbine member according to claim 2, wherein the deposited carbon film contains 0 to 40 at % hydrogen and/or 0 to 30 at % nitrogen.

13. The steam turbine member according to claim 2, wherein the deposited carbon film has a thickness of 100 nm to 8 μm.

14. The steam turbine member according to claim 2, wherein a graphite amount G (%) in a carbon component and a hydrogen content H (at %) satisfy, in a surface region of the deposited carbon film, a relationship represented by the following formula (1):
$$H \geq 1.5118 \times G - 40.603 \qquad ( 1 )$$

15. The steam turbine member according to claim 2, wherein the deposited carbon film has a maximum height roughness Rz of at most 6.3 μm.

16. The steam turbine member according to claim 2, wherein the deposited carbon film is provided above the base material through an intermediate layer.

17. The steam turbine member according to claim 2, wherein the steam turbine member is a first stage stationary blade.

18. A steam turbine, comprising the steam turbine member according to claim 2.
